(19) United States
(12) Patent Application Publication
(10) Pub. No.: US 2009/0308732 A1
(43) Pub. Date: Dec. 17, 2009

(54) APPARATUS AND METHOD FOR UNIFORM DEPOSITION

(75) Inventors: Yong Cao, San Jose, CA (US); Maurice E. Ewert, San Jose, CA (US); Xianmin Tang, San Jose, CA (US); Keith A. Miller, Sunnyvale, CA (US); Daniel C. Lubben, San Jose, CA (US); Umesh M. Kelkar, Santa Clara, CA (US); Tza-Jing Gung, San Jose, CA (US); Anantha K. Subramani, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/482,713

(22) Filed: Jun. 11, 2009

Related U.S. Application Data
(60) Provisional application No. 61/073,130, filed on Jun. 17, 2008.

(51) Int. Cl. C23C 14/34

(52) U.S. Cl. 204/192.12; 204/298.11; 204/298.06

(57) ABSTRACT

Embodiments of the present invention generally relate to an apparatus and method for uniform sputter depositing of materials into the bottom and sidewalls of high aspect ratio features on a substrate. In one embodiment, a sputter deposition system includes a collimator that has apertures having aspect ratios that decrease from a central region of the collimator to a peripheral region of the collimator. In one embodiment, the collimator is coupled to a grounded shield via a bracket member that includes a combination of internally and externally threaded fasteners. In another embodiment, the collimator is integrally attached to a grounded shield. In one embodiment, a method of sputter depositing material includes pulsing the bias on the substrate support between high and low values.

### CROSS-REFERENCE TO RELATED APPLICATIONS

This application claims benefit of U.S. provisional patent application Ser. No. 61/073,130 (Attorney Docket No. 12996L, filed Jun. 17, 2008, which is herein incorporated by reference.

This application is related to U.S. patent application Ser. No. ______, filed (Attorney Docket No. 12996.02).

### BACKGROUND OF THE INVENTION

1. Field of the Invention

Embodiments of the present invention generally relate to an apparatus and method for uniform sputter depositing of materials onto the bottom and sidewalls of high aspect ratio features on a substrate.

2. Description of the Related Art

Sputtering, or physical vapor deposition (PVD), is a widely used technique for depositing thin metal layers on substrates in the fabrication of integrated circuits. PVD is used to deposit layers for use as diffusion barriers, seed layers, primary conductors, antireflection coatings, and etch stops. However, with PVD it is difficult to form a uniform, thin film that conforms to the shape of a substrate where a step occurs, such as a via or trench formed in the substrate. In particular, the broad angular distribution of depositing sputtered atoms leads to poor coverage in the bottom and sidewalls of high aspect ratio features, such as vias and trenches.

One technique developed to allow the use of PVD to deposit thin films in the bottom of a high aspect ratio feature is collimator sputtering. A collimator is a filtering plate positioned between a sputtering source and a substrate. The collimator typically has a uniform thickness and includes a number of passages formed through the thickness. Sputtered material must pass through the collimator on its path from the sputtering source to the substrate. The collimator filters out material that would otherwise strike the workpiece at acute angles exceeding a desired angle.

The actual amount of filtering accomplished by a given collimator depends on the aspect ratio of the passages through the collimator. As such, particles traveling on a path approaching normal to the substrate pass through the collimator and are deposited on the substrate. This allows improved coverage in the bottom of high aspect ratio features.

However, certain problems exist with the use of prior art collimators in conjunction with small magnet magnetrons. Use of small magnet magnetrons may produce a highly ionized metal flux, which may be advantageous in filling high aspect ratio features. Unfortunately, PVD with a prior art collimator in combination with a small magnet magnetron provides non-uniform deposition across a substrate. Thicker layers of source material may be deposited in one region of the substrate than in other regions of the substrate. For example, thicker layers may be deposited near the center or the edge of the substrate, depending on the radial positioning of the small magnet. This phenomenon not only leads to non-uniform deposition across the substrate, but it also leads to non-uniform deposition across high aspect ratio feature sidewalls in certain regions of the substrate as well. For instance, a small magnet positioned radially to provide optimum field uniformity in the region near the perimeter of the substrate, leads to source material being deposited more heavily on feature sidewalls that face the center of the substrate than those that face the perimeter of the substrate.

Therefore, a need exists for improvements in the uniformity of depositing source materials across a substrate by PVD techniques.

### SUMMARY OF THE INVENTION

In one embodiment of the present invention a deposition apparatus comprises an electrically grounded chamber, a sputtering target supported by the chamber and electrically isolated from the chamber, a substrate support pedestal positioned below the sputtering target and having a substrate support surface substantially parallel to the sputtering surface of the sputtering target, a shield member supported by the chamber and electrically coupled to the chamber, and a collimator mechanically and electrically coupled to the shield member and positioned between the sputtering target and the substrate support pedestal. In one embodiment, the collimator has a plurality of apertures extending therethrough. In one embodiment, the apertures located in a central region have a higher aspect ratio than the apertures located in a peripheral region.

In one embodiment, a deposition apparatus comprises an electrically grounded chamber, a sputtering target supported by the chamber and electrically isolated from the chamber, a substrate support pedestal positioned below the sputtering target and having a substrate support surface substantially parallel to the sputtering surface of the sputtering target, a shield member supported by the chamber and electrically coupled to the chamber, a collimator mechanically and electrically coupled to the shield member and positioned between the sputtering target and the substrate support pedestal, a gas source, and a controller. In one embodiment, the sputtering target is electrically coupled to a DC power source. In one embodiment, the substrate support pedestal is electrically coupled to an RF power source. In one embodiment, the controller is programmed to provide signals to control the gas source, DC power source, and the RF power source. In one embodiment, the collimator has a plurality of apertures extending therethrough. In one embodiment the apertures located in a central region have a higher aspect ratio than the apertures located in a peripheral region of the collimator. In one embodiment, the controller is programmed to provide high bias to the substrate support pedestal.

In one embodiment, a method for depositing material onto a substrate comprises applying a DC bias to a sputtering target in a chamber having a collimator positioned between the sputtering target and a substrate support pedestal, providing a processing gas in a region adjacent the sputtering target within the chamber, applying a bias to the substrate support pedestal, and pulsing the bias applied to the substrate support pedestal between a high bias and a low bias. In one embodiment, the collimator has a plurality of apertures extending therethrough. In one embodiment, the apertures located in a central region have a higher aspect ratio than the apertures located in a peripheral region of the collimator.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic, cross-sectional views of physical deposition (PVD) chambers according to embodiments of the present invention.

FIG. 2 is a schematic, plan view of a collimator according to one embodiment of the present invention.

FIG. 3 is a schematic, cross-sectional view of a collimator according to one embodiment of the present invention.

FIG. 4 is a schematic, cross-sectional view of a collimator according to one embodiment of the present invention.

FIG. 5 is a schematic, cross-sectional view of a collimator according to one embodiment of the present invention.

FIG. 6 is an enlarged, partial cross-sectional view of a bracket for attaching a collimator to an upper shield of a PVD chamber according to one embodiment of the present invention.

FIG. 7 is an enlarged, partial cross-sectional view of a bracket for attaching a collimator to an upper shield of a PVD chamber according to one embodiment of the present invention.

FIG. 8 is a schematic, plan view of a monolithic collimator according to one embodiment of the present invention.

### DETAILED DESCRIPTION

Embodiments of the present invention provide apparatus and methods for uniform deposition of sputtered material across high aspect ratio features of a substrate during the fabrication of integrated circuits on substrates.

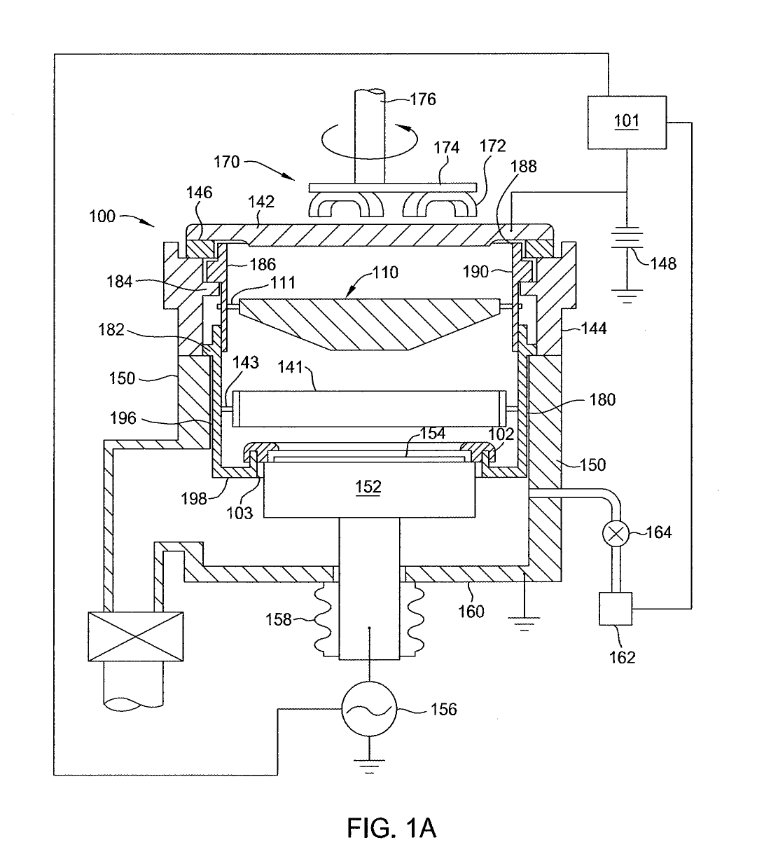

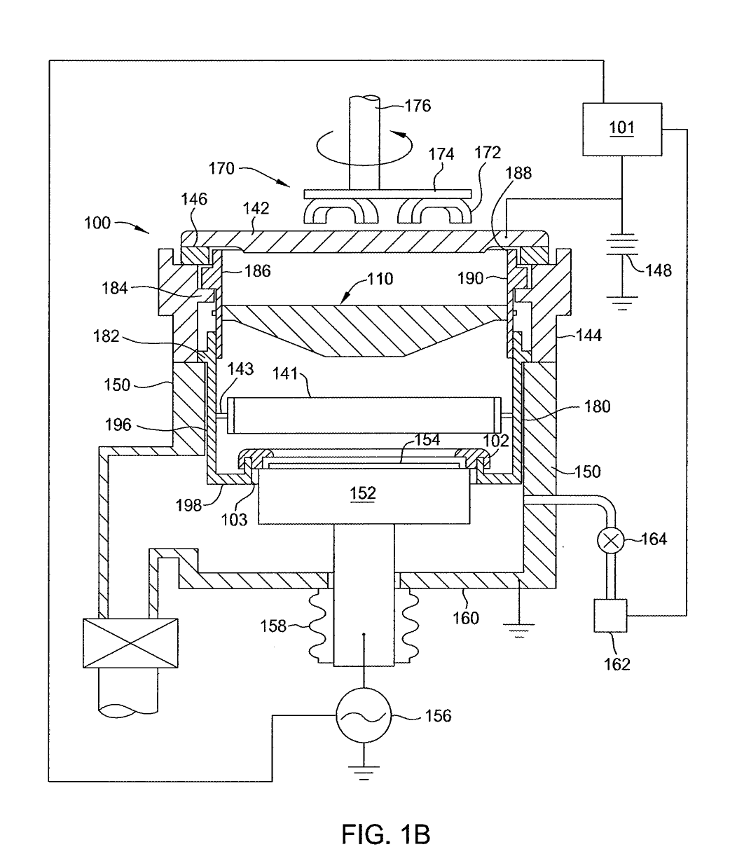

FIGS. 1A and 1B are schematic, cross-sectional views of physical deposition (PVD) chambers according to embodiments of the present invention. The PVD chamber 100 includes a sputtering source, such as a target 142, and a substrate support pedestal 152 for receiving a semiconductor substrate 154 thereon. The substrate support pedestal may be located within a grounded chamber wall 150.

In one embodiment, the chamber 100 includes the target 142 supported by a grounded conductive adapter 144 through a dielectric isolator 146. The target 142 comprises the material to be deposited on the substrate 154 surface during sputtering, and may include copper for depositing as a seed layer in high aspect ratio features formed in the substrate 154. In one embodiment, the target 142 may also include a bonded composite of a metallic surface layer of sputterable material, such as copper, and a backing layer of a structural material, such as aluminum.

In one embodiment, the pedestal 152 supports a substrate 154 having high aspect ratio features to be sputter coated, the bottoms of which are in planar opposition to a principal surface of the target 142. The substrate support pedestal 152 has a planar substrate-receiving surface disposed generally parallel to the sputtering surface of the target 142. The pedestal 152 may be vertically movable through a bellows 158 connected to a bottom chamber wall 160 to allow the substrate 154 to be transferred onto the pedestal 152 through a load lock valve (not shown) in a lower portion of the chamber 100. The pedestal 152 may then be raised to a deposition position as shown.

In one embodiment, processing gas may be supplied from a gas source 162 through a mass flow controller 164 into the lower portion of the chamber 100. In one embodiment, a controllable direct current (DC) power source 148, coupled to the chamber 100, may be used to apply a negative voltage or bias to the target 142. A radio frequency (RF) power source 156 may be coupled to the pedestal 152 to induce a DC self-bias on the substrate 154. In one embodiment, the pedestal 152 is grounded. In one embodiment, the pedestal 152 is electrically floated.

In one embodiment, a magnetron 170 is positioned above the target 142. The magnetron 170 may include a plurality of magnets 172 supported by a base plate 174 connected to a shaft 176, which may be axially aligned with the central axis of the chamber 100 and the substrate 154. In one embodiment, the magnets are aligned in a kidney-shaped pattern. The magnets 172 produce a magnetic field within the chamber 100 near the front face of the target 142 to generate plasma, such that a significant flux of ions strike the target 142, causing sputter emission of target material. The magnets 172 may be rotated about the shaft 176 to increase uniformity of the magnetic field across the surface of the target 142. In one embodiment, the magnetron 170 is a small magnet magnetron. In one embodiment, the magnets 172 may be both rotated and moved reciprocally in a linear direction substantially parallel to the face of the target 142 to produce a spiral motion. In one embodiment, the magnets 172 may be rotated about both a central axis and an independently-controlled secondary axis to control both their radial and angular positions.

In one embodiment, the chamber 100 includes a grounded lower shield 180 having an upper flange 182 supported by and electrically coupled to the chamber sidewall 150. An upper shield 186 is supported by and electrically coupled to a flange 184 of the adapter 144. The upper shield 186 and the lower shield 180 are electrically coupled as are the adapter 144 and the chamber wall 150. In one embodiment, the upper shield 186 and the lower shield 180 are each comprised of a material selected from aluminum, copper, and stainless steel. In one embodiment, the chamber 100 includes a middle shield (not shown) coupled to the upper shield 186. In one embodiment, the upper shield 186 and lower shield 180 are electrically floating within the chamber 100. In one embodiment, the upper shield 186 and lower shield 180 are coupled to an electrical power source.

In one embodiment, the upper shield 186 has an upper portion that closely fits an annular side recess of the target 142 with a narrow gap 188 between the upper shield 186 and the target 142, which is sufficiently narrow to prevent plasma from penetrating and sputter coating the dielectric isolator 146. The upper shield 186 may also include a downwardly projecting tip 190, which covers the interface between the lower shield 180 and the upper shield 186, preventing them from being bonded by sputter deposited material.

In one embodiment, the lower shield 180 extends downwardly into a tubular section 196, which generally extends along the chamber wall 150 to below the top surface of the pedestal 152. The lower shield 180 may have a bottom section 198 extending radially inward from the tubular section 196. The bottom section 198 may include an upwardly extending inner lip 103 surrounding the perimeter of the pedestal 152. In one embodiment, a cover ring 102 rests on the top of the lip 103 when the pedestal 152 is in a lower, loading position and rests on the outer periphery of the pedestal 152 when the pedestal is in an upper, deposition position to protect the pedestal 152 from sputter deposition.

In one embodiment, directional sputtering may be achieved by positioning a collimator 110 between the target 142 and the substrate support pedestal 152. The collimator 110 may be mechanically and electrically coupled to the upper shield 186 via a plurality of radial brackets 111, as shown in FIG. 1A. In one embodiment, the collimator 110 is coupled to a middle shield (not shown), positioned lower in the chamber 100. In one embodiment, the collimator 110 is integral to the upper shield 186, as shown in FIG. 1B. In one embodiment, the collimator 110 is welded to the upper shield 186. In one embodiment, the collimator 110 may be electrically floating within the chamber 100. In one embodiment, the collimator 110 is coupled to an electrical power source.

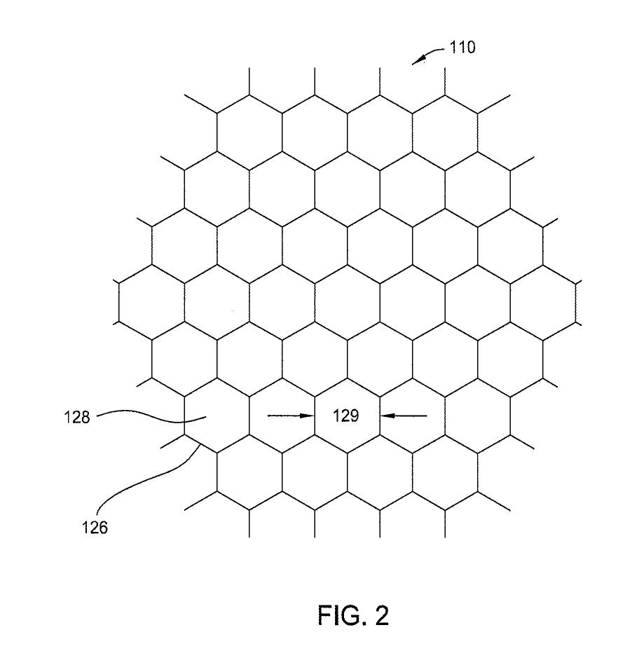

FIG. 2 is a top plan view of one embodiment of the collimator 110. The collimator 110 is generally a honeycomb structure having hexagonal walls 126 separating hexagonal apertures 128 in a close-packed arrangement. An aspect ratio of the hexagonal apertures 128 may be defined as the depth of the aperture 128 (equal to the thickness of the collimator) divided by the width 129 of the aperture 128. In one embodiment, the thickness of the walls 126 is between about 0.06 inches and about 0.18 inches. In one embodiment, the thickness of the walls 126 is between about 0.12 inches and about 0.15 inches. In one embodiment, the collimator 110 is comprised of a material selected from aluminum, copper, and stainless steel.

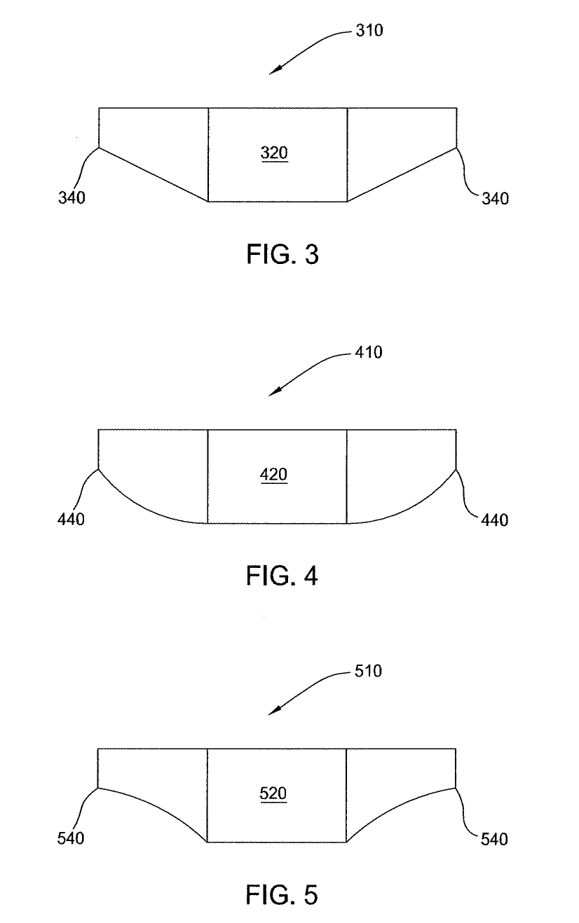

FIG. 3 is a schematic, cross-sectional view of a collimator 310 according to one embodiment of the present invention. The collimator 310 includes a central region 320 having a high aspect ratio, such as from about 1.5:1 to about 3:1. In one embodiment, the aspect ratio of the central region 320 is about 2.5:1. The aspect ratio of collimator 310 decreases along with the radial distance from the central region 320 to an outer peripheral region 340. In one embodiment, the aspect ratio of the collimator 310 decreases from a central region 320 aspect ratio of about 2.5:1 to a peripheral region 340 aspect ratio of about 1:1. In another embodiment, the aspect ratio of the collimator 310 decreases from a central region 320 aspect ratio of about 3:1 to a peripheral region 340 aspect ratio of about 1:1. In one embodiment, the aspect ratio of the collimator 310 decreases from a central region 320 aspect ratio of about 1.5:1 to a peripheral region 340 aspect ratio of about 1:1.

In one embodiment, the radial aperture decrease of the collimator 310 is accomplished by varying the thickness of the collimator 310. In one embodiment, the central region 320 of the collimator 310 has an increased thickness, such as between about 3 inches to about 6 inches. In one embodiment, the thickness of the central region 320 of the collimator 310 is about 5 inches. In one embodiment, the thickness of the collimator 310 decreases from the central region 320 to the outer peripheral region 340. In one embodiment, the thickness of the collimator 310 radially decreases from a central region 320 thickness of about 5 inches to a peripheral region 340 thickness of about 2 inches. In one embodiment, the thickness of the collimator 310 radially decreases from a central region 320 thickness of about 6 inches to a peripheral region 340 thickness of about 2 inches. In one embodiment, the thickness of the collimator 310 radially decreases from a central region 320 thickness of about 2.5 inches to about 2 inches.

Although the variance in the aspect ratio of the embodiment of collimator 310 depicted in FIG. 3 shows a radially decreasing thickness, the aspect ratio may alternatively be decreased by increasing the width of the apertures of the collimator 310 from the central region 320 to the peripheral region 340. In another embodiment, the thickness of the collimator 310 is decreased and the width of apertures of the collimator 310 is increased from the central region 320 to the peripheral region 340.

Generally, the embodiment in FIG. 3 depicts the aspect ratio radially decreasing in a linear fashion, resulting in an inverted conical shape. Other embodiments of the present invention may include non-linear decreases in the aspect ratio.

FIG. 4 is a schematic, cross-sectional view of a collimator 410 according to one embodiment of the present invention. The collimator 410 has a thickness that decreases from a central region 420 to a peripheral region 440 in a non-linear fashion, resulting in a convex shape.

FIG. 5 is a schematic, cross-sectional view of a collimator 510 according to one embodiment of the present invention. The collimator 510 has a thickness that decreases from a central region 520 to a peripheral region 540 in a nonlinear fashion, resulting in a concave shape.

In some embodiments, the central region 320, 420, 520 approaches zero, such that the central region 320, 420, 520 appears as a point on the bottom of the collimator 310, 410, 510.

Referring back to FIGS. 1A and 1B, the operation of the PVD process chamber 100 and the function of the collimator 110 are similar regardless of the exact shape of the radial decreasing aspect ratio of the collimator 110. A system controller 101 is provided outside of the chamber 100 and generally facilitates control and automation of the overall system. The system controller 101 may include a central processing unit (CPU) (not shown), memory (not shown), and support circuits (not shown). The CPU may be one of any computer processors used in industrial settings for controlling various system functions and chamber processes.

In one embodiment, the system controller 101 provides signals to position the substrate 154 on the substrate support pedestal 152 and generate plasma in the chamber 100. The system controller 101 sends signals to apply a voltage via DC power source 148 to bias the target 142 and to excite processing gas, such as argon, into plasma. The system controller 101 may further provide signals to cause the RF power source 156 to DC self-bias the pedestal 152. The DC self-bias helps attract positively charged ions created in the plasma deeply into high aspect ratio vias and trenches on the surface of the substrate.

The collimator 110 functions as a filter to trap ions and neutrals that are emitted from the target 142 at angles exceeding a selected angle, near normal to the substrate 154. The collimator 110 may be one of the collimators 310, 410, or 510, depicted in FIG. 3, 4, or 5, respectively. The characteristic of the collimator 110 of having an aspect ratio that decreases radially from the center allows a greater percentage of ions emitted from peripheral regions of the target 142 to pass through the collimator 110. As a result, both the number of ions and the angle of arrival of ions deposited onto peripheral regions of the substrate 154 are increased. Therefore, according to embodiments of the present invention, material may be more uniformly sputter deposited across the surface of the substrate 154. Additionally, material may be more uniformly deposited on the bottom and sidewalls of high aspect ratio features, particularly high aspect ratio vias and trenches located near the periphery of the substrate 154.

Additionally, in order to provide even greater coverage of sputter deposited material onto the bottom and sidewalls of high aspect ratio features, material sputter deposited onto the field and bottom regions of features may be sputter etched. In one embodiment, the system controller 101 applies a high bias to the pedestal 152 such that the target 142 ions etch film already deposited on the substrate 152. As a result, the field deposition rate onto the substrate 154 is reduced, and the sputtered material re-deposits on either the sidewalls or bottom of the high aspect ratio features. In one embodiment, the system controller 101 applies high and low bias to the pedestal 152 in a pulsing, or alternating fashion such that the process becomes a pulsing deposit/etch process. In one embodiment, the collimator 110 cells specifically located below magnets 172 direct the majority of the deposition material toward the substrate 154. Therefore, at any particular time, material in one region of the substrate 154 may be deposited, while material already deposited in another region of the substrate 154 may be etched.

In one embodiment, to provide even greater coverage of sputter deposited material onto the sidewalls of high aspect ratio features, material sputter deposited onto the bottom of the features may be sputter etched using secondary plasma, such as argon plasma, generated in a region of the chamber 100 near the substrate 154. In one embodiment, the chamber 100 includes an RF coil 141 attached to the lower shield 180 by a plurality of coil standoffs 143, which electrically insulate the coil 141 from the lower shield 180. The system controller 101 sends signals to apply RF power through the shield 180 to the coil 141 via feedthrough standoffs (not shown). In one embodiment, the RF coil inductively couples RF energy into the interior of the chamber 100 to ionize precursor gas, such as argon, to maintain secondary plasma near the substrate 154. The secondary plasma resputters a deposition layer from the bottom of a high aspect ratio feature and redeposits the material onto the sidewalls of the feature.

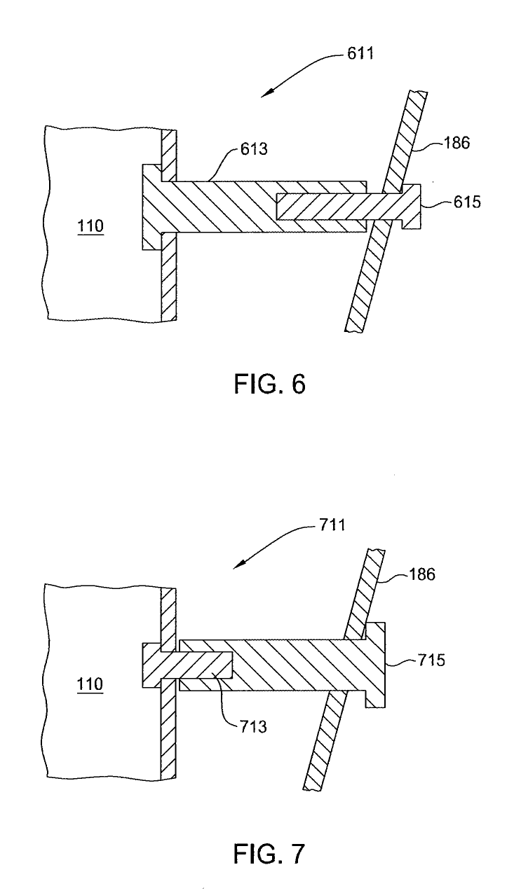

Referring to FIG. 1A, the collimator 110 may be attached to the upper shield 186 by a plurality of radial brackets 111. FIG. 6 is an enlarged, cross-sectional view of a bracket 611 for attaching the collimator 110 to the upper shield 186 according to one embodiment of the present invention. The bracket 611 includes an internally threaded tube 613 that is welded to the collimator 110 and extends radially outward therefrom. A fastening member 615, such as a screw, may be inserted through an aperture in the upper shield 186 and threaded into the tube 613 to attach the collimator 110 to the upper shield 186, while minimizing the potential for depositing material onto the threaded portion of the tube 613 or the fastening member 615.

FIG. 7 is an enlarged, cross-sectional view of a bracket 711 for attaching the collimator 110 to the upper shield 186 according to another embodiment of the present invention. The bracket 711 includes a stud 713 that is welded to the collimator 110 and extends radially outward therefrom. An internally threaded fastening member 715 may be inserted through an aperture in the upper shield 186 and threaded onto the stud 713 to attach the collimator 110 to the upper shield 186, while minimizing the potential for depositing material onto threaded portions of the stud 713 or the fastening member 715.

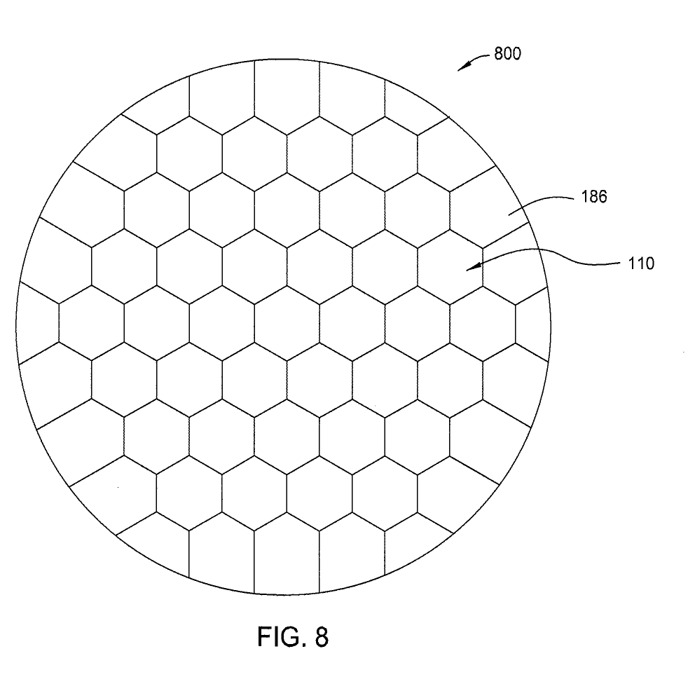

Referring to FIG. 1B, the collimator 110 may be integral to the upper shield 186. FIG. 8 is a schematic, plan view of a monolithic collimator 800 according to one embodiment of the present invention. In this embodiment, the collimator 110 is integral to the upper shield 186. In one embodiment, the outer perimeter of the collimator 110 may be attached to the inner perimeter of the upper shield 186 via welding or other bonding techniques.

While the foregoing is directed to embodiments of the present invention, other and further embodiments of the invention may be devised without departing from the basic scope thereof, and the scope thereof is determined by the claims that follow.

1. A deposition apparatus, comprising:
an electrically grounded chamber;
a sputtering target supported by the chamber and electrically isolated from the chamber;
a substrate support pedestal positioned below the sputtering target and having a substrate support surface substantially parallel to the sputtering surface of the sputtering target;
a shield member supported by the chamber; and
a collimator mechanically and electrically coupled to the shield member and positioned between the sputtering target and the substrate support pedestal, wherein the collimator has a plurality of apertures extending therethrough and wherein the apertures located in a central region have a higher aspect ratio than the apertures located in a peripheral region.

2. The apparatus of claim 1, wherein the thickness of the collimator is greater in the central region than in the peripheral region.

3. The apparatus of claim 1, wherein the aspect ratio of the apertures decreases continuously from the central region to the peripheral region.

4. The apparatus of claim 3, wherein the thickness of the collimator continuously decreases from the central region to the peripheral region.

5. The apparatus of claim 1, wherein the aspect ratio of the apertures decreases linearly from the central region to the peripheral region.

6. The apparatus of claim 5, wherein the thickness of the collimator decreases linearly from the central region to the peripheral region.

7. The apparatus of claim 1, wherein the aspect ratio of the apertures decreases nonlinearly from the central region to the peripheral region.

8. The apparatus of claim 7, wherein the thickness of the collimator decreases nonlinearly from the central region to the peripheral region.

9. The apparatus of claim 1, wherein the collimator is coupled to the shield member via a bracket, comprising:
an externally threaded member; and
an internally threaded member engaged with the externally threaded member.

10. The apparatus of claim 9, wherein the externally threaded member is welded to the collimator.

11. The apparatus of claim 9, wherein the internally threaded member is welded to the collimator.

12. The apparatus of claim 1, wherein the collimator is welded to the shield member.

13. The apparatus of claim 1, wherein the collimator is integral to the shield member.

14. The apparatus of claim 1, wherein the collimator is comprised of a material selected from the group consisting of aluminum, copper, and stainless steel.

15. The apparatus of claim 1, wherein the collimator has a wall thickness between the apertures from between about 0.06 inches and about 0.18 inches.

16. A deposition apparatus, comprising:
an electrically grounded chamber;
a sputtering target supported by the chamber and electrically isolated from the chamber and electrically coupled to a DC power source;
a substrate support pedestal positioned below the sputtering target and having a substrate support surface substantially parallel to the sputtering surface of the sputtering target, wherein the substrate support pedestal is electrically coupled to an RF power source;
a shield member supported by the chamber and electrically coupled to the chamber;
a collimator mechanically and electrically coupled to the shield member and positioned between the sputtering target and the substrate support pedestal, wherein the collimator has a plurality of apertures extending therethrough and wherein the apertures located in a central region have a higher aspect ratio than the apertures located in a peripheral region;
a gas source; and
a controller programmed to provide signals to control the gas source, DC power source, and the RF power source, wherein the controller is programmed to provide high bias to the substrate support pedestal.

17. The apparatus of claim 16, wherein the controller is programmed to provide signals to control the RF power source such that the substrate support pedestal alternates between high and low bias.

18. The apparatus of claim 17, further comprising an RF coil, wherein the controller is programmed to control power supplied to the RF coil and the gas source to control a secondary plasma in the chamber.

19. The apparatus of claim 18, wherein the aspect ratio of the apertures decreases linearly from the central region to the peripheral region.

20. The apparatus of claim 19, wherein the thickness of the collimator decreases linearly from the central region to the peripheral region.

21. A method for depositing material onto a substrate, comprising:
applying a DC bias to a sputtering target in a chamber having a collimator positioned between the sputtering target and a substrate support pedestal, wherein the collimator has a plurality of apertures extending therethrough, and wherein the apertures located in a central region have a higher aspect ratio than the apertures located in a peripheral region;
providing a processing gas in a region adjacent the sputtering target within the chamber;
applying a bias to the substrate support pedestal; and
pulsing the bias applied to the substrate support pedestal between a high bias and a low bias.

22. The method of claim 21, further comprising applying power to an RF coil positioned inside the chamber to provide a secondary plasma inside the chamber.

23. The method of claim 22, wherein the aspect ratio of the apertures decreases linearly from the central region to the peripheral region.
